(19) United States
(12) Patent Application Publication
(10) Pub. No.: US 2011/0269314 A1
(43) Pub. Date: Nov. 3, 2011

(54) PROCESS CHAMBERS HAVING SHARED RESOURCES AND METHODS OF USE THEREOF

(75) Inventors: JARED AHMAD LEE, Santa Clara, CA (US); JAMES P. CRUSE, Santa Cruz, CA (US); ANDREW NGUYEN, San Jose, CA (US); CORIE LYNN COBB, Mountain View, CA (US); MING XU, San Jose, CA (US); MARTIN JEFF SALINAS, San Jose, CA (US); ANCHEL SHEYNER, San Francisco, CA (US)

(73) Assignee: APPLIED MATERIALS, INC., Santa Clara, CA (US)

(21) Appl. No.: 12/905,032

(22) Filed: Oct. 14, 2010

Related U.S. Application Data
(60) Provisional application No. 61/330,014, filed on Apr. 30, 2010.

(51) Int. Cl. H01L 21/3065

(52) U.S. Cl. 438/715; 156/345.52; 156/345.48; 156/345.31

(57) ABSTRACT

Process chambers having shared resources and methods of use are provided. In some embodiments, substrate processing systems may include a first process chamber having a first substrate support disposed within the first process chamber, wherein the first substrate support has a first heater and a first cooling plate to control a temperature of the first substrate support; a second process chamber having a second substrate support disposed within the second process chamber, wherein the second substrate support has a second heater and a second cooling plate to control a temperature of the second substrate support; and a shared heat transfer fluid source having an outlet to provide a heat transfer fluid to the first cooling plate and the second cooling plate and an inlet to receive the heat transfer fluid from the first cooling plate and the second cooling plate.

### CROSS-REFERENCE TO RELATED APPLICATIONS

This application claims benefit of United States provisional patent application Ser. No. 61/330,014, filed Apr. 30, 2010, which is herein incorporated by reference.

### FIELD

Embodiments of the present invention generally relate to substrate processing systems.

### BACKGROUND

To facilitate an increased manufacturing rate of semiconductor products, multiple substrates may be fabricated simultaneously within a processing system. A conventional processing system may be configured as a cluster tool, comprising two or more process chambers coupled to a transfer chamber. Each of the process chambers is provided a number of processing resources via a resource supply to facilitate performing the particular process therein. For example, one such processing resource is a heat transfer fluid provided by a heat transfer fluid supply to facilitate temperature control over one or more parts of the process chamber. Typically, each process chamber within a processing system has a heat transfer fluid supply respectively coupled thereto. Each heat transfer fluid supply includes a reservoir that is maintained at a desired temperature. However, a large amount of energy is required to maintain the heat transfer fluid at the desired temperature within each of the reservoirs of the heat transfer fluid supplies, resulting in a costly and inefficient system.

Accordingly, the inventors have provided process chambers having shared resources and methods of use thereof to improve efficiency of substrate manufacturing and reduce cost of processing systems.

### SUMMARY

Process chambers having shared resources and methods of use are provided herein. In some embodiments, a substrate processing system may include a first process chamber having a first substrate support disposed within the first process chamber, wherein the first substrate support has a first heater and a first cooling plate to circulate a heat transfer fluid through the first cooling plate to control a temperature of the first substrate support; a second process chamber having a second substrate support disposed within the second process chamber, wherein the second substrate support has a second heater and a second cooling plate to control a temperature of the second substrate support; and a shared heat transfer fluid source having an outlet to provide the heat transfer fluid to the first cooling plate and the second cooling plate and an inlet to receive the heat transfer fluid from the first cooling plate and the second cooling plate.

In some embodiments, a method of processing substrates in a twin chamber processing system having shared processing resources may include heating a first substrate disposed on a first substrate support in a first process chamber of a twin chamber processing system to a first temperature using a first heater disposed in the first substrate support and maintaining the first temperature of the first substrate by flowing a heat transfer fluid through a first cooling plate disposed in the first substrate support; heating a second substrate disposed on a second substrate support in a second process chamber of the twin chamber processing system to the first temperature using a second heater disposed in the second substrate support and maintaining the first temperature of the second substrate by flowing a heat transfer fluid through a second cooling plate disposed in the second substrate support, wherein the heat transfer fluid is supplied to the first and second cooling plates by a shared heat transfer fluid source; and performing a first process on the first and second substrates when the first temperature is reached for each substrate in each of the first process chamber and the second process chamber.

In some embodiments, a method of processing substrates in a twin chamber processing system having shared processing resources may include maintaining a first substrate disposed on a first substrate support in a first process chamber of a twin chamber processing system at a first temperature by flowing a heat transfer fluid from a heat transfer fluid source through the first substrate support; maintaining a second substrate disposed on a second substrate support in a second process chamber of the twin chamber processing system at the first temperature by flowing the heat transfer fluid from the heat transfer fluid source through the second substrate support, wherein the heat transfer fluid source is coupled to the first and second substrate supports in parallel; and performing a first process on the first and second substrates when the first temperature is reached for each substrate in each of the first process chamber and the second process chamber.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts an exemplary processing system suitable for use with one or more process chambers having shared resources in accordance with some embodiments of the present invention.

FIG. 2 depicts two exemplary process chambers suitable for use with shared resources in accordance with some embodiments of the present invention.

FIG. 3 is a method of processing substrates in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Process chambers having shared resources and methods of use thereof are provided herein. The inventive methods and apparatus may advantageously provide shared resources, for example a shared heat transfer fluid supply, to a plurality of more process chambers within a processing system simultaneously, thereby increasing the efficiency of a processing system and reducing the cost to operate.

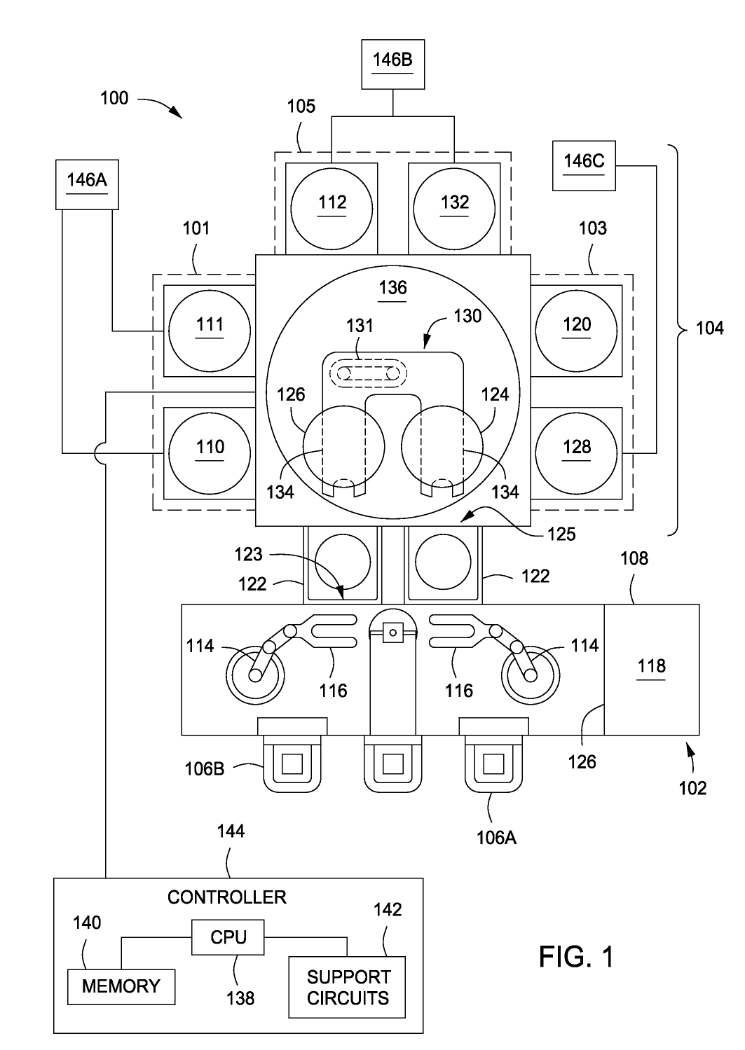

Referring to FIG. 1, in some embodiments, a processing system 100 may generally comprise a vacuum-tight processing platform 104, a factory interface 102, and a system controller 144. Examples of a processing system that may be suitably modified in accordance with the teachings provided herein include the Centura® integrated processing system, one of the PRODUCER® line of processing systems (such as the PRODUCER® GT™), ADVANTEDGE™ processing systems, or other suitable processing systems commercially available from Applied Materials, Inc., located in Santa Clara, Calif. It is contemplated that other processing systems (including those from other manufacturers) may be adapted to benefit from the invention.

The platform 104 may include a plurality of processing chambers (six shown) 110, 111, 112, 132, 128, 120 and at least one load-lock chamber (two shown) 122 that are coupled to a transfer chamber 136. Each process chamber includes a slit valve or other selectively sealable opening to selectively fluidly couple the respective inner volumes of the process chambers to the inner volume of the transfer chamber 136. Similarly, each load lock chamber 122 includes a port to selectively fluidly couple the respective inner volumes of the load lock chambers 122 to the inner volume of the transfer chamber 136. The factory interface 102 is coupled to the transfer chamber 136 via the load lock chambers 122.

In some embodiments, for example, as depicted in FIG. 1, the processing chambers 110, 111, 112, 132, 128, 120 may be grouped in pairs with each of the processing chambers 110 and 111, 112 and 132, and 128 and 120 in each pair positioned adjacent to one another. In some embodiments, each pair of process chambers may be part of a twin chamber processing system (101, 103, 105) where each respective pair of process chambers may be provided in a common housing with certain shared resources provided, as discussed herein. Each twin chamber processing system 101, 103, 105 may include a pair of independent processing volumes that may be isolated from each other. For example, each twin chamber processing system may include a first process chamber and a second process chamber, having respective first and second processing volumes. The first and second processing volumes may be isolated from each other to facilitate substantially independent processing of substrates in each respective process chamber. The isolated processing volumes of the process chambers within the twin chamber processing system advantageously reduces or eliminates processing problems that may arise due to multi-substrate processing systems where the processing volumes are fluidly coupled during processing.

In addition, the twin chamber processing system further advantageously utilizes shared resources that facilitate reduced system footprint, hardware expense, utilities usage and cost, maintenance, and the like, while at the same time promoting higher substrate throughput. For example, as shown in FIG. 1, the processing chambers may be configured such that processing resources 146A, 146B, 146C (collectively 146) (i.e., process gas supply, power supply, or the like) may be respectively shared between each of the processing chambers 110 and 111, 112 and 132, and 128 and 120, and/or within each pair of processing chamber in each twin processing system 101, 103, 105. Other examples of shared hardware and/or resources may include one or more of a process foreline and roughing pump, AC distribution and DC power supplies, cooling water distribution, chillers, multi-channel thermo controllers, gas panels, controllers, and the like. One example of a twin chamber processing system that may be modified in accordance with the present invention is described in U.S. Provisional Patent Application Ser. No. 61/330,156, filed Apr. 30, 2010, by Ming Xu et al., and entitled, “Twin Chamber Processing System.”

In some embodiments, the factory interface 102 comprises at least one docking station 108 and at least one factory interface robot (two shown) 114 to facilitate transfer of substrates. The docking station 108 is configured to accept one or more (two shown) front opening unified pods (FOUPs) 106A-B. In some embodiments, the factory interface robot 114 generally comprises a blade 116 disposed on one end of the robot 114 configured to transfer the substrate from the factory interface 102 to the processing platform 104 for processing through the load lock chambers 122. Optionally, one or more metrology stations 118 may be connected to a terminal 126 of the factory interface 102 to facilitate measurement of the substrate from the FOUPs 106A-B.

In some embodiments, each of the load lock chambers 122 may include a first port 123 coupled to the factory interface 102 and a second port 125 coupled to the transfer chamber 136. The load lock chambers 122 may be coupled to a pressure control system which pumps down and vents the load lock chambers 122 to facilitate passing the substrate between the vacuum environment of the transfer chamber 136 and the substantially ambient (e.g., atmospheric) environment of the factory interface 102.

In some embodiments, the transfer chamber 136 has a vacuum robot 130 disposed therein. The vacuum robot 130 generally comprises a one or more transfer blades (two shown) 134 coupled to a movable arm 131. In some embodiments, for example where the processing chambers 110, 111, 112, 132, 128, 120 are arranged in groups of two, as depicted FIG. 1, the vacuum robot 130 may comprise a two parallel transfer blades 134 configured such that the vacuum robot 130 may simultaneously transfer two substrates 124 from the load lock chambers 122 to each pair of processing chambers (110 and 111, 112 and 132, and 128 and 120).

The processing chambers 110, 111, 112, 132, 128, 120 may be any type of process chamber utilized in substrate processing. However, to utilize the shared resources, each pair of processing chambers is the same type of chamber, such as an etch chamber, a deposition chamber, or the like. Non-limiting examples of suitable etch chambers that may be modified in accordance with the teachings provided herein include any of the Decoupled Plasma Source (DPS) line of chambers, a HART™, E-MAX®, or ENABLER® etch chamber available from Applied

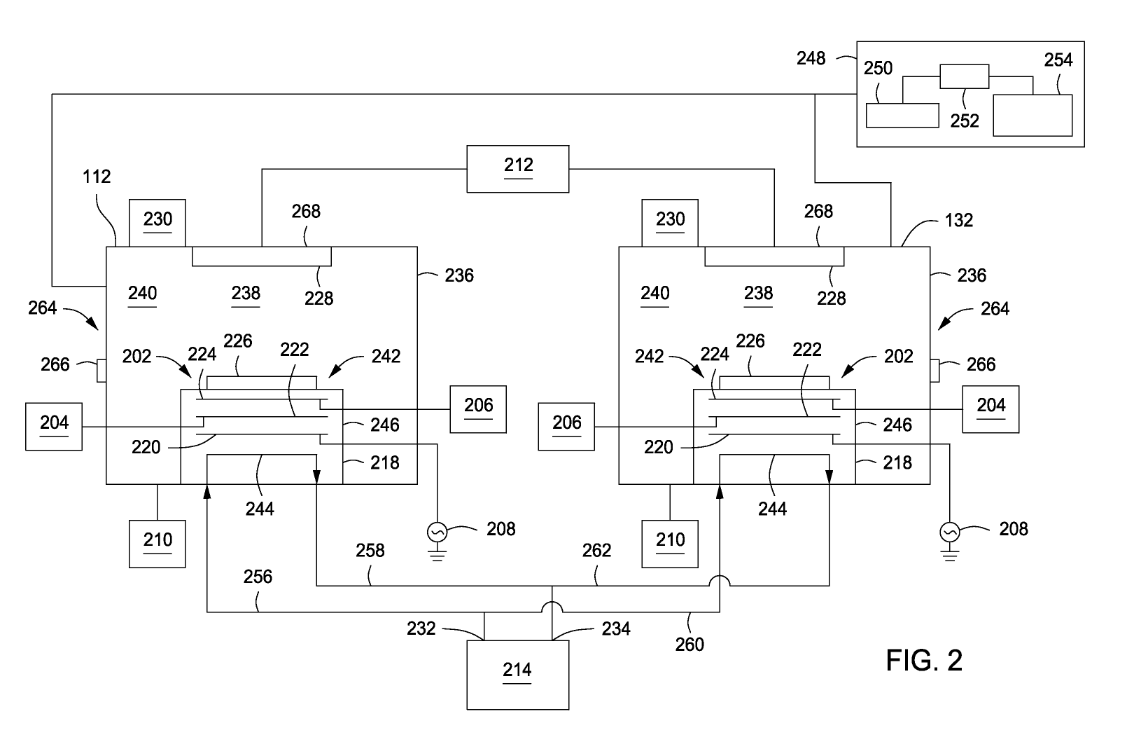

Materials, Inc., of Santa Clara, Calif. In some embodiments, one or more of the process chambers 110, 111, 112, 132, 128, 120 may be similar to the process chambers described below with respect to FIG. 2. Other etch chambers, including those from other manufacturers, may be utilized.

The system controller 144 is coupled to the processing system 100. The system controller 144 controls the operation of the system 100 using a direct control of the process chambers 110, 111, 112, 132, 128, 120 of the system 100 or alternatively, by controlling the computers (or controllers) associated with the process chambers 110, 111, 112, 132, 128, 120 and the system 100. In operation, the system controller 144 enables data collection and feedback from the respective chambers and system controller 144 to optimize performance of the system 100.

The system controller 144 generally includes a central processing unit (CPU) 138, a memory 140, and support circuits 142. The CPU 138 may be one of any form of a general purpose computer processor that can be used in an industrial setting. The memory, or computer-readable medium, 140 is accessible by the CPU 138 and may be one or more of readily available memory such as random access memory (RAM), read only memory (ROM), floppy disk, hard disk, or any other form of digital storage, local or remote. The support circuits 142 are conventionally coupled to the CPU 138 and may comprise cache, clock circuits, input/output subsystems, power supplies, and the like. The inventive methods disclosed herein may generally be stored in the memory 140 (or in memory of a particular process chamber pair, as discussed below) as a software routine that, when executed by the CPU 138, causes the pair of process chambers to perform processes in accordance with the present invention.

FIG. 2 depicts two exemplary process chambers 112, 132 suitable for use in conjunction with one or more shared resources in accordance with some embodiments of the present invention. The process chambers 112, 132 may be any type of process chamber, for example, such as the process chambers described above with respect to FIG. 1. Each of the process chambers 112, 132 may be the same type of process chamber, and in some embodiments, may be part of a twin chamber processing system (such as the twin chamber processing system 105 shown in FIG. 1). In some embodiments, each process chamber is an etch chamber and is part of a twin chamber processing system.

In some embodiments, each process chamber (e.g., 112, 132) may generally comprise a chamber body 236 having an inner volume 240 that may include a processing volume 238. The processing volume 238 may be defined, for example, between a substrate support pedestal 202 disposed within the process chamber 112, 132 for supporting a substrate 226 thereupon during processing and one or more gas inlets, such as a showerhead 228 and/or nozzles provided at desired locations.

In some embodiments, the substrate support pedestal 202 may include a mechanism that retains or supports the substrate 226 on the surface 242 of the substrate support pedestal 202, such as an electrostatic chuck, a vacuum chuck, a substrate retaining clamp, or the like. For example, in some embodiments, the substrate support pedestal 202 may include a chucking electrode 224 disposed within an electrostatic chuck 246. The chucking electrode 224 may be coupled to one or more chucking power sources (one chucking power source 206 per chamber shown) through one or more respective matching networks (not shown). The one or more chucking power source 206 may be capable of producing up to 12,000 W at a frequency of about 2 MHz, or about 13.56 MHz, or about 60 Mhz. In some embodiments, the one or more chucking power source 206 may provide either continuous or pulsed power. In some embodiments, the chucking power source may be a DC or pulsed DC source.

In some embodiments, the substrate support 202 may include one or more mechanisms for controlling the temperature of the substrate support surface 242 and the substrate 226 disposed thereon. For example, one or more channels 244 may be provided to define one or more flow paths beneath the substrate support surface 242 to flow a heat transfer fluid. The one or more channels 244 may be configured in any manner suitable to provide adequate control over temperature profile across the substrate support surface 242 and the substrate 226 disposed thereon during processing. In some embodiments, the one or more channels 244 may be disposed within a cooling plate 218. In some embodiments, the cooling plate 218 may be disposed beneath the electrostatic chuck 246.

The heat transfer fluid may comprise any fluid suitable to provide adequate transfer of heat to or from the substrate 226. For example, the heat transfer fluid may be a gas, such as helium (He), oxygen (O₂), or the like, or a liquid, such as water, antifreeze, or an alcohol, for example, glycerol, ethylene glycerol, propylene, methanol, or the like.

A shared heat transfer fluid source 214 may simultaneously supply the one or more channels 244 of each process chamber 112, 132 with the heat transfer fluid. In some embodiments, the shared heat transfer fluid source 214 may be coupled to each process chamber 112, 132 in parallel. For example, the shared heat transfer fluid source 214 comprises at least one outlet 232 coupled to one or more supply conduits (one per chamber shown) 256, 260 to provide the heat transfer fluid to the one or more channels 244 of each of the respective process chambers 112, 132. In some embodiments, each of the supply conduits 256, 260 may have a substantially similar fluid conductance. As used herein, substantially similar fluid conductance means within +/−10 percent. For example, in some embodiments, each of the supply conduits 256, 260 may have a substantially similar cross sectional area and axial length, thereby providing a substantially similar fluid conductance. Alternatively, in some embodiments, each of the supply conduits 256, 260 may comprise different dimensions, for example such as a different cross sectional area and/or axial length, thereby each providing a different fluid conductance. In such embodiments, different dimensions of each of the supply conduits 256, 260 may provide different flow rates of heat transfer fluid to each of the one or more channels 244 of each of the process chambers 112, 132.

Additionally, the shared heat transfer fluid source 214 comprises at least one inlet 234 coupled to one or more return conduits (one per chamber shown) 258, 262 to receive the heat transfer fluid from the one or more channels 244 of each of the respective process chambers 112, 132. In some embodiments, each of the supply return conduits 258, 262 may have a substantially similar fluid conductance. For example, in some embodiments, each of the return conduits 258, 262 may comprise a substantially similar cross sectional area and axial length. Alternatively, in some embodiments, each of the return conduits 258, 262 may comprise different dimensions, for example such as a different cross sectional area and/or axial length.

The shared heat transfer fluid source 214 may include a temperature control mechanism, for example a chiller and/or heater, to control the temperature of the heat transfer fluid. One or more valves or other flow control devices (not shown) may be provided between the heat transfer fluid source 214 and the one or more channels 244 to independently control a rate of flow of the heat transfer fluid to each of the process chambers 112, 132. A controller (not shown) may control the operation of the one or more valves and/or of the shared heat transfer fluid source 214.

In operation, the shared heat transfer fluid source 214 may provide a heat transfer fluid at a predetermined temperature to each of the one or more channels 244 of each of the process chambers 112, 132 via the supply conduits 256, 260. As the heat transfer fluid flows through the one or more channels 244 of the substrate support 202, the heat transfer fluid either provides heat to, or removes heat from the substrate support 202, and therefore the substrate support surface 242 and the substrate 226 disposed thereon. The heat transfer fluid then flows from the one or more channels 244 back to the shared heat transfer fluid source 214 via the return conduits 258, 262, where the heat transfer fluid is heated or cooled to the predetermined temperature via the temperature control mechanism of the shared heat transfer fluid source 214.

In some embodiments, one or more heaters (one per chamber shown) 222 may be disposed proximate the substrate support 202 to further facilitate control over the temperature of the substrate support surface 242. The one or more heaters 222 may be any type of heater suitable to provide control over the substrate temperature. For example, the one or more heaters 222 may be one or more resistive heaters. In such embodiments, the one or more heaters 222 may be coupled to a power source 204 configured to provide the one or more heaters 222 with power to facilitate heating the one or more heaters 222. In some embodiments the heaters may be disposed above or proximate to the substrate support surface 242. Alternatively, or in combination, in some embodiments, the heaters may be embedded within the substrate support 202 or the electrostatic chuck 246. The number and arrangement of the one or more heaters may be varied to provide additional control over the temperature of the substrate 226. For example, in embodiments where more than one heater is utilized, the heaters may be arranged in a plurality of zones to facilitate control over the temperature across the substrate 226, thus providing increased temperature control.

The substrate 226 may enter the process chamber 112, 132 via an opening 264 in a wall of the process chamber 112, 132. The opening 264 may be selectively sealed via a slit valve 266, or other mechanism for selectively providing access to the interior of the chamber through the opening 264. The substrate support pedestal 202 may be coupled to a lift mechanism (not shown) that may control the position of the substrate support pedestal 202 between a lower position suitable for transferring substrates into and out of the chamber via the opening 264 and a selectable upper position suitable for processing. The process position may be selected to maximize process uniformity for a particular process. When in at least one of the elevated processing positions, the substrate support pedestal 202 may be disposed above the opening 264 to provide a symmetrical processing region.

The one or more gas inlets (e.g., the showerhead 228) may be coupled to independent or a shared gas supply (shared gas supply 212 shown) for providing one or more process gases into the processing volume 238 of the process chambers 112, 132. For example, a showerhead 228 disposed proximate a ceiling 268 of the process chamber is shown in FIG. 2. However, additional or alternative gas inlets may be provided, such as nozzles or inlets disposed in the ceiling or on the sidewalls of the process chambers 112, 132 or at other locations suitable for providing gases as desired to the process chambers 112, 132, such as the base of the process chamber, the periphery of the substrate support pedestal, or the like.

In some embodiments, the process chambers 112, 132 may utilize capacitively coupled RF power for plasma processing, although the process chambers 112, 132 may also or alternatively use inductive coupling of RF power for plasma processing. For example, the substrate support 202 may have an electrode 220 disposed therein, or a conductive portion of the substrate support 202 may be used as the electrode. The electrode may be coupled to one or more plasma power sources (one RF power source 208 per process chamber shown) through one or more respective matching networks (not shown). In some embodiments, for example where the substrate support 202 is fabricated from a conductive material (e.g., a metal such as aluminum) the conductive portion of the substrate support 202 may function as an electrode, thereby eliminating the need for a separate electrode 220. The one or more plasma power sources may be capable of producing up to about 5,000 W at a frequency of about 2 MHz and or about 13.56 MHz or high frequency, such as 27 MHz and/or 60 MHz.

In some embodiments, endpoint detection systems 230 may be coupled to each of the process chambers 112, 132 and used to determine when a desired endpoint of a process is reached in each chamber. For example, the endpoint detection system 230 may be one or more of an optical spectrometer, a mass spectrometer, or any suitable detection system for determining the endpoint of a process being performed within the processing volume 238. In some embodiments, the endpoint detection system 230 may be coupled to a controller 248 of the process chambers 112, 132. Although a single controller 248 is shown for the process chambers 112, 132 (as may be used in a twin chamber processing system), individual controllers may alternatively be used.

A vacuum pump 210 may be coupled to the pumping plenum via a pumping port for pumping out the exhaust gases from the process chambers 112, 132. The vacuum pump 210 may be fluidly coupled to an exhaust outlet for routing the exhaust as required to appropriate exhaust handling equipment. A valve (such as a gate valve or the like) may be disposed in the pumping plenum to facilitate control of the flow rate of the exhaust gases in combination with the operation of the vacuum pump 210.

To facilitate control of the process chambers 112, 132, the controller 248 may be one of any form of general-purpose computer processor that can be used in an industrial setting for controlling various chambers and sub-processors. The memory, or computer-readable medium, 250 of the CPU 252 may be one or more of readily available memory such as random access memory (RAM), read only memory (ROM), floppy disk, hard disk, or any other form of digital storage, local or remote. The support circuits 254 are coupled to the CPU 252 for supporting the processor in a conventional manner. These circuits include cache, power supplies, clock circuits, input/output circuitry and subsystems, and the like.

The inventive methods disclosed herein may generally be stored in the memory 250 as a software routine that, when executed by the CPU 252, causes the process chambers 112, 132 to perform processes of the present invention. The software routine may also be stored and/or executed by a second CPU (not shown) that is remotely located from the hardware being controlled by the CPU 252. Some or all of the method of the present invention may also be performed in hardware. As such, the invention may be implemented in software and executed using a computer system, in hardware as, e.g., an application specific integrated circuit or other type of hardware implementation, or as a combination of software and hardware. The software routine, when executed by the CPU 252, transforms the general purpose computer into a specific purpose computer (controller) 248 that controls the chamber operation such that the methods disclosed herein are performed.

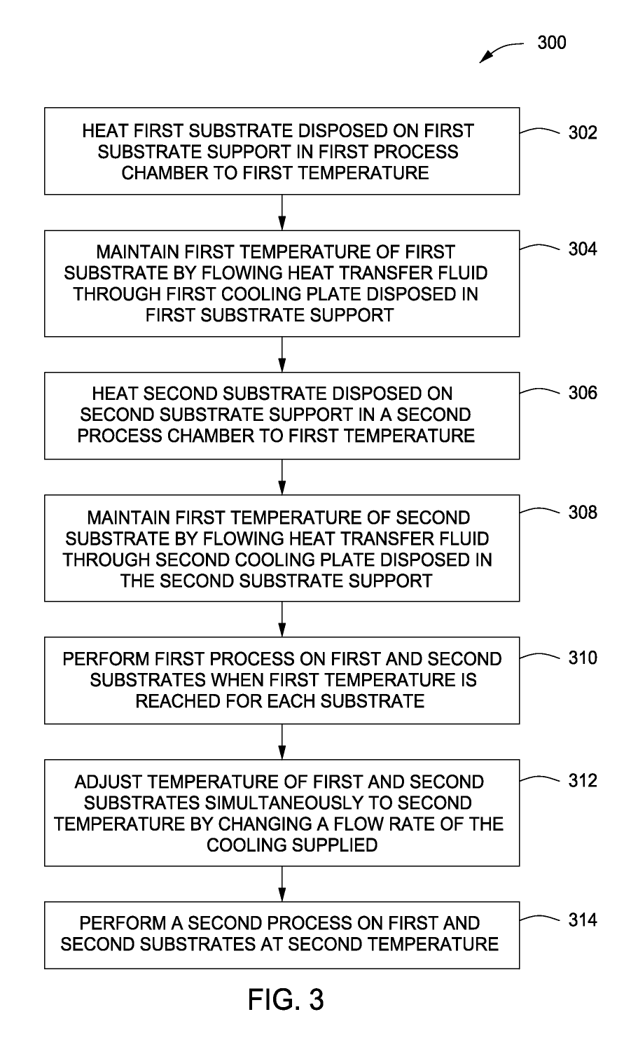

For example, FIG. 3 depicts a flow chart of a method 300 for processing substrates in accordance with some embodiments of the present invention. The method 300 may be performed in any suitable process chamber, such as two or more process chambers similar to the process chambers 112, 132 described above with respect to FIGS. 1 and 2.

The method 300 generally begins at 302 where a first substrate disposed on a first substrate support in a first process chamber (e.g. substrate 226 disposed on substrate support 202 of process chamber 112 of FIG. 2) is heated to a first temperature. The first temperature may be any temperature required to facilitate performing a desired process. The substrate may be heated via any means suitable and to any temperature required for a particular process being performed. For example, in some embodiments, the substrate may be heated via a heater embedded within the first substrate support, for example, such as heater 222 embedded within substrate support 202 of process chamber 112 described above.

Next, at 304, the first temperature is maintained by flowing heat transfer fluid through a first cooling plate disposed in the first substrate support. In some embodiments, the heat transfer fluid may be provided via a shared heat transfer fluid supply, for example the shared heat transfer fluid source 214 coupled to process chambers 112, 132 described above. In some embodiments, the cooling plate may be similar to the cooling plate 218 disposed in the substrate support 202 of process chamber 112 described above. In such embodiments, the heat transfer fluid may be provided to the cooling plate 218 via one or more supply conduits 256. The heat transfer fluid may comprise any fluid suitable to provide adequate transfer of heat to or from the substrate. For example, the heat transfer fluid may be a gas, such as helium (He), oxygen (O₂), or the like, or a liquid, such as water, antifreeze, or an alcohol, for example, glycerol, ethylene glycerol, propylene, methanol, or the like. The heat transfer fluid may be provided at any flow rate needed to maintain the first temperature. In some embodiments, the flow rate may be held at a constant flow rate, or in some embodiments adjusted dynamically to maintain the first temperature at or near a desired temperature. The heat transfer fluid may also be provided at a desired temperature, for example, by heating or cooling the heat transfer fluid to a desired temperature setpoint within the shared heat transfer fluid source 214.

Next, at 306, a second substrate disposed on a second substrate support in a second process chamber is heated to the first temperature. (e.g. substrate 226 disposed on substrate support 202 of process chamber 132 of FIG. 2) is heated to a first temperature. The first temperature may be any temperature required to facilitate performing a desired process. The substrate may be heated via any means suitable and to any temperature required for a particular process being performed. For example, in some embodiments, the substrate may be heated via a heater embedded within the first substrate support, for example, such as heater 222 embedded within substrate support 202 of process chamber 132 described above.

Next, at 308, the first temperature is maintained by flowing a heat transfer fluid through a second cooling plate disposed in the second substrate support. In some embodiments, the heat transfer fluid may be provided via a shared heat transfer fluid supply, for example the shared heat transfer fluid source 214 coupled to process chambers 112, 132 described above. In some embodiments, the cooling plate may be similar to the cooling plate 218 disposed in the substrate support 202 of process chamber 132 described above. In such embodiments, the heat transfer fluid may be provided to the cooling plate 218 via one or more supply conduits 260. The heat transfer fluid may comprise any fluid suitable to provide adequate transfer of heat to or from the substrate, for example, any of the fluids described above. The heat transfer fluid may be provided at any flow rate needed to maintain the first temperature. In some embodiments the flow rate may be the same as, or in some embodiments, different than that of the flow rate of the heat transfer fluid provided to the first substrate support. In some embodiments, the flow rate may be held at a constant flow rate, or in some embodiments adjusted dynamically to maintain the first temperature at a constant temperature. In some embodiments, the first and second substrates may be brought to the first temperature in parallel—meaning that at least some, and preferably most or all, of the time required for the first substrate to be heated to and maintained at the first temperature and for the second substrate to be heated to and maintained at the first temperature overlap.

Next, at 310, a first process is performed on the first and second substrates. The first process may be any process that can be performed during substrate fabrication, for example, an etch, deposition, anneal, or the like. In some embodiments, the first process performed on the first substrate is the same as the first process performed on the second substrate. In some embodiments, the first process performed on the first substrate may be different from the first process performed on the second substrate, for example, if the temperature setpoints are the same or close enough to operate using the shared heat transfer fluid source 214.

Next, at 312, in some embodiments, the temperature of first and second substrates may be substantially simultaneously adjusted to a second temperature by changing a flow rate of the heat transfer fluid. For example, the flow rate of heat transfer fluid may be increased or decreased to decrease or increase (when the heat transfer fluid removes heat from substrate) or to increase or decrease (when the heat transfer fluid heats the substrate) the temperature of first and second substrates to the second temperature. The temperature of the first and second substrates may be adjusted at any time during or after the first process is performed on the first and second substrates. For example, in some embodiments, the temperature of the first and second substrates may be adjusted to the second temperature when an endpoint of the first process performed on either or both of the first and second substrates is detected. For example, in some embodiments, the first process may be monitored and the endpoint of the first process may be detected using an endpoint detection system in each of the first and second process chambers, such at the endpoint detection system 230 of process chambers 112, 132 described above.

In some embodiments, the endpoint of the first process performed on the first and second substrates may be reached simultaneously. In such embodiments, the temperature of first and second substrates may then be simultaneously adjusted. Alternatively, in some embodiments, the endpoint of the first process performed on the first and second substrates may not be reached simultaneously. In such embodiments, the first process may be terminated in the process chamber where the endpoint was reached and continued in the other chamber until the first endpoint is reached. The temperature of first and second substrates may then be simultaneously adjusted.

Optionally, at 314, a second process may be performed on the first and second substrates. The second process may be any process that can be performed during substrate fabrication, for example, an etch, deposition, anneal, or the like. In some embodiments, the second process performed on the first substrate is the same at the second process performed on the second substrate. In some embodiments, the second process performed on the first substrate is different from the second process performed on the second substrate. In some embodiments, the second process performed on the first and second substrates may be the same as the first process performed on the first and second substrates, or in some embodiments, the second process performed on the first and second substrates may be different from as the first process performed on the first and second substrates

After the second process is performed at 314, the method 300 generally ends at 314 and the first and second substrates may proceed for subsequent processes or additional fabrication steps.

Thus, process chambers having shared resources and methods of use thereof have been provided herein. The inventive apparatus and method may advantageously provide shared resources, for example a shared heat transfer fluid supply, to one or more process chambers within a processing system simultaneously, thereby increasing the efficiency of a processing system and reducing the cost to operate.

While the foregoing is directed to embodiments of the present invention, other and further embodiments of the invention may be devised without departing from the basic scope thereof.

1. A substrate processing system, comprising:
a first process chamber having a first substrate support disposed within the first process chamber, wherein the first substrate support has one or more channels to circulate a heat transfer fluid to control a temperature of the first substrate support;
a second process chamber having a second substrate support disposed within the second process chamber, wherein the second substrate support has one or more channels to circulate the heat transfer fluid to control a temperature of the second substrate support; and
a shared heat transfer fluid source having an outlet to provide the heat transfer fluid to the respective one or more channels of the first substrate support and the second substrate support and an inlet to receive the heat transfer fluid from the first substrate support and the second substrate support.

2. The substrate processing system of claim 1, further comprising:
a first chucking electrode disposed in the first substrate support of the first process chamber for electrostatically coupling a substrate to the first substrate support; and
a second chucking electrode disposed in the second substrate support of the second process chamber for electrostatically coupling a substrate to the second substrate support.

3. The substrate processing system of claim 1, further comprising:
a first RF electrode disposed in the first substrate support and configured to receive RF power from an RF source; and
a second RF electrode disposed in the second substrate support and configured to receive RF power from an RF source.

4. The substrate processing system of claim 1, further comprising:
a shared gas panel to provide a process gas to both the first and second process chambers.

5. The substrate processing system of claim 1:
wherein the first substrate support further comprises a first heater and a first cooling plate, wherein the one or more channels to circulate the heat transfer fluid are disposed in the first cooling plate; and
wherein the second substrate support further comprises a second heater and a second cooling plate, wherein the one or more channels to circulate the heat transfer fluid are disposed in the second cooling plate.

6. The substrate processing system of claim 5, further comprising:
a first inlet conduit coupled between the shared inlet of the shared heat transfer fluid source and the first inlet of the first cooling plate;
a first outlet conduit coupled between the shared outlet of the shared heat transfer fluid source and the first outlet of the first cooling plate;
a second inlet conduit coupled between the shared inlet of the shared heat transfer fluid source and the second inlet of the second cooling plate; and
a second outlet conduit coupled between the shared outlet of the shared heat transfer fluid source and the second outlet of the second cooling plate;

7. The substrate processing system of claim 6, wherein the first and second inlet conduits and the first and second outlet conduits have substantially equal flow conductance.

8. The substrate processing system of claim 1, further comprising:
a central vacuum transfer chamber, wherein the first and second process chambers are coupled to the central vacuum transfer chamber.

9. A method of processing substrates in a twin chamber processing system having shared processing resources, comprising:
heating a first substrate disposed on a first substrate support in a first process chamber of a twin chamber processing system to a first temperature using a first heater disposed in the first substrate support and maintaining the first temperature of the first substrate by flowing a heat transfer fluid through a first cooling plate disposed in the first substrate support;
heating a second substrate disposed on a second substrate support in a second process chamber of the twin chamber processing system to the first temperature using a second heater disposed in the second substrate support and maintaining the first temperature of the second substrate by flowing a heat transfer fluid through a second cooling plate disposed in the second substrate support, wherein the heat transfer fluid is supplied to the first and second cooling plates by a shared heat transfer fluid source; and
performing a first process on the first and second substrates when the first temperature is reached for each substrate in each of the first process chamber and the second process chamber.

10. The method of claim 9, further comprising:
adjusting a temperature of the first and second substrates to a second temperature by changing a flow rate of the heat transfer fluid supplied by the shared heat transfer fluid source to each of the first and second cooling plates when an endpoint for the process has been reached in at least one of the first or second process chambers; and
performing a second process on the first and second substrates at the second temperature.

11. The method of claim 9, further comprising:
monitoring a first processing volume of the first process chamber with a first endpoint detection system and the second processing volume of the second process chamber with a second endpoint detection system to determine if the endpoint for the first process is reached in either volume.

12. The method of claim 11, further comprising:
terminating the first process in the first and second process chambers when a first endpoint is reached in the first processing volume.

13. The method of claim 12, wherein the first endpoint is reached prior to a second endpoint in the second processing volume for processing the second substrate.

14. The method of claim 12, wherein the first endpoint is reached after a second endpoint in the second processing volume for processing the second substrate.

15. The method of claim 12, further comprising:
adjusting the temperature of the first and second substrates to a second temperature by adjusting the flow rate of the heat transfer fluid to the first and second cooling plates after the first endpoint is reached.

16. The method of claim 9, further comprising:
terminating the first process in the first process chamber when an endpoint is reached in the first process chamber while continuing the first process in the second process chamber until an endpoint is reached in the second process chamber; and
adjusting the temperature of the first and second substrates to the second temperature by adjusting the flow rate of the heat transfer fluid to the first and second cooling plates after the endpoint for the first process is reached in both the first and second process chambers.

17. The method of claim 9, wherein the heat transfer fluid is supplied to a first inlet of the first cooling plate and a second inlet of the second cooling plate from a shared outlet of the shared heat transfer fluid source and wherein the heat transfer fluid is returned from a first outlet of the first cooling plate and a second outlet of the second cooling plate to a shared inlet of the shared heat transfer fluid source.

18. The method of claim 17, further comprising:
flowing the heat transfer fluid from the shared outlet to each of the first and second cooling plates at a substantially similar flow rate.

19. The method of claim 17, further comprising:
flowing the heat transfer fluid through a first heat transfer fluid path from the shared outlet of the shared heat transfer fluid source through the first cooling plate to the shared inlet of the shared heat transfer fluid source; and
flowing the heat transfer fluid through a second heat transfer fluid path from the shared outlet through the second cooling plate to the shared inlet, wherein the first and second heat transfer fluid paths have substantially equivalent flow conductance.

20. A method of processing substrates in a twin chamber processing system having shared processing resources, comprising:
maintaining a first substrate disposed on a first substrate support in a first process chamber of a twin chamber processing system at a first temperature by flowing a heat transfer fluid from a heat transfer fluid source through the first substrate support;
maintaining a second substrate disposed on a second substrate support in a second process chamber of the twin chamber processing system at the first temperature by flowing the heat transfer fluid from the heat transfer fluid source through the second substrate support, wherein the heat transfer fluid source is coupled to the first and second substrate supports in parallel; and
performing a first process on the first and second substrates when the first temperature is reached for each substrate in each of the first process chamber and the second process chamber.
